(19) United States
(12) Patent Application Publication
(10) Pub. No.: US 2014/0023697 A1
(43) Pub. Date: Jan. 23, 2014

(54) METHODS AND SYSTEMS FOR NANOMEMBRANE CRYSTALLIZATION

(71) Applicant: SUNGHEE LEE DIMAURO, Stamford, CT (US)

(72) Inventor: SUNGHEE LEE DIMAURO, Stamford, CT (US)

(73) Assignee: IONA COLLEGE, New Rochelle, NY (US)

(21) Appl. No.: 13/897,324

(22) Filed: May 17, 2013

Related U.S. Application Data
(60) Provisional application No. 61/672,756, filed on Jul. 17, 2012.
(60) Provisional application No. 61/696,782, filed on Sep. 4, 2012.

(51) Int. Cl. C30B 7/00

(52) U.S. Cl. CPC C30B 7/00
USPC 424/450; 117/70; 514/785

(57) ABSTRACT

In one aspect, embodiments of the invention provide a method, the method comprising contacting at least one osmotic body and a droplet comprising solvent and at least one solute. The contacting forms at least one thin film between the droplet and the at least one osmotic body. The method further comprises allowing solvent to transfer between the droplet and the at least one osmotic body, to form a precipitate of the at least one solute.

### CROSS-REFERENCE TO RELATED CASES

The present application is a nonprovisional of, and claims benefit to, prior-filed copending provisional patent application Ser. No. 61/672756 filed Jul. 17 2012, entitled NANOMEMBRANE CRYSTALLIZATION: METHODS, SYSTEMS, AND COMPOSITIONS; the latter application is hereby incorporated by reference in its entirety. The present application is also a nonprovisional of, and claims benefit to, prior-filed copending provisional patent application Ser. No. 61/696782 filed Sep. 4, 2012 titled NANOMEMBRANE CRYSTALLIZATION II; METHODS, SYSTEMS, AND COMPOSITIONS; the latter application is also hereby incorporated by reference in its entirety.

### GOVERNMENT DATA

This invention was made with government support under NSF-CHE-0909978 awarded by the National Science Foundation. The government has certain rights in the invention.

### FIELD

Aspects of the invention generally relate to formation of a crystal and/or precipitate in a droplet, and more particularly, relate to a formation of a crystal and/or precipitate in a droplet through solvent transfer from the droplet across a thin film and into an osmotic body.

### BACKGROUND

The development of new methods for controlling crystallization continues to have growing significance for pure and applied chemistry, as well as providing new platforms for the greater understanding of biological processes. Crystal engineering techniques which can result in desired shape, size, and molecular structure, hold great promise for materials chemistry. For example, much effort has been devoted to the synthesis of nanocrystals, in understanding the process of biomineralization, and in precise control of active pharmaceutical crystal forms. Moreover, advances in structural proteomics increasingly require newer and faster techniques for crystallizing proteins, especially integral membrane proteins. For example, methods for crystallization of target solutes in droplet microfluidic systems have recently come to the forefront, owing to their capability of handling high-throughput, using small amount of solute needed for crystallization, and flexibility in achieving various conditions conducive to crystallization. In turn, development of such techniques will depend upon achieving greater control of crystal nucleation, growth, size, and form.

As one way to control desired crystallization outcome, many groups have employed confinement methods. Ensuring that crystal nucleation occurs in a small space has proven useful in isolating metastable polymorphs. Another important parameter pertinent to crystallization is the ability to control the rate at which supersaturation is achieved prior to the critical nucleation step. The supersaturation rate has previously been shown in certain cases to strongly affect the outcome of a nucleation process, such as for glycine form control.

Improved methods for forming crystals at desired rates are continuously in demand.

### BRIEF SUMMARY

In one aspect, embodiments of the invention provide a method, the method comprising contacting at least one osmotic body and a droplet comprising solvent and at least one solute. The contacting forms at least one thin film between the droplet and the at least one osmotic body. The method further comprises allowing solvent to transfer between the droplet and the at least one osmotic body, to form a precipitate of the at least one solute.

In another aspect, embodiments of the invention provide a composition comprising a plurality of compartments comprising at least one crystalline active pharmaceutical ingredient. These compartments are encapsulated by a lipid bilayer, and this composition has been made by a process in accordance with the method of the paragraph immediately above.

In another aspect, embodiments of the invention provide a composition comprising a plurality of compartments comprising at least one crystalline active pharmaceutical ingredient; these compartments are encapsulated by a lipid bilayer. This composition has been made by a process comprising at least a step of water transfer across a lipid bilayer from a plurality of droplets comprising an aqueous solution of the active pharmaceutical ingredient. The plurality of compartments is derived from the plurality of droplets.

In another aspect, embodiments of the invention provide a composition comprising at least one first aqueous droplet adhering to at least one second aqueous droplet at an interface. The interface comprises a droplet interface bilayer. The at least one first aqueous droplet comprises at least one solute, and the at least one second aqueous droplet comprises at least one osmolyte. The at least one first aqueous droplet further comprises at least one crystal of the at least one solute.

In another aspect, embodiments of the invention provide a composition comprising a plurality of first aqueous droplets comprising at least one solute, and a plurality of second aqueous droplets comprising at least one osmotyte. At least one of the plurality of first aqueous droplets is adhering to at least one of the plurality of second aqueous droplets at an interface, the interface comprising a droplet interface bilayer. At least one of the plurality of first aqueous droplets further comprises at least one crystal of the at least one solute.

### BRIEF DESCRIPTION OF THE FIGURES

FIG. 1A depicts a schematic view of an exemplary system in accordance with an embodiment of the invention.

FIG. 1B depicts another schematic view of an exemplary system in accordance with an embodiment of the invention.

FIG. 1C depicts yet another schematic view of an exemplary system in accordance with an embodiment of the invention.

FIG. 2 is a schematic diagram of an exemplary droplet system in accordance with an embodiment of the invention.

FIG. 3 depicts a schematic view of an exemplary microfluidic system in accordance with an embodiment of the invention.

FIG. 4 is a schematic depiction of an exemplary arrayed system in accordance with an embodiment of the invention.

FIG. 5 shows the formation of a monoolein bilayer in accordance with aspects of the invention and measurements of contact angle.

FIG. 6 shows the effect of water transport across a droplet interface bilayer to form crystals of a first inorganic salt (FIG. 6A) and a second inorganic salt (FIG. 6B).

### DETAILED DESCRIPTION

Aspects of the present invention relate to a method comprising contacting at least one osmotic body, and a droplet which comprises solvent and at least one solute, to form at least one thin film between the droplet and the at least one osmotic body; and allowing solvent to transfer between the droplet and the at least one osmotic body to form a precipitate of the at least one solute. Generally, this method may be characterized as being a method capable of crystallizing a water-soluble solute. The term “target droplet” is defined as a droplet which comprises solvent and at least one solute, wherein the at least one solute is intended to be precipitated (e.g., crystallized) as a result of the method.

A “thin film”, as the term is used herein, is defined as a membrane having a thickness of less than about 20 nm, e.g., from about 1 nm to about 20 nm. In some embodiments, a thin film may have a thickness of between about 2 nm and about 10 nm. In other embodiments, the thin film may have a thickness of from about 2 nm to about 20 nm, or from about 10 nm to about 20 nm.

In many embodiments, a thin film of the present disclosure may comprise a bilayer, e.g., a lipid bilayer, such as a phospholipid bilayer. Such a bilayer may comprise at least one bilayer-forming amphiphile, e.g., a bilayer-forming lipid such as a phospholipid or monoglyceride. In some embodiments, a thin film may comprise a bola-amphiphile, or an oligomer or polymer, e.g., at least one block copolymer such as an poly(alkyl)alkylene-polyalkyleneoxide block copolymer. Many of the block copolymers which are suitable for formation of polymersomes may be components of the present thin film; the person of ordinary skill may readily determine, without undue experimentation, which block copolymers are suitable. In some embodiments, the thin film may be a semipermeable membrane, i.e., a membrane capable of substantially allowing water to pass across the thin film to the substantial exclusion of other species. In certain embodiments, the present thin film may be referred to as a “nanomembrane”, owing to its thickness in the nanometer range and its capability of acting as a semipermeable membrane. The above-described aspects of a thin film may be combinable: in some embodiments, the thin film may comprise a phospholipid bilayer which is capable of acting as a membrane which is semipermeable to water.

As used herein, a droplet has its ordinary and normal meaning, as would be well understood by persons having skill in the art. In accordance with embodiments, a droplet may be a watery fluid pool or compartment in contact with a hydrophobic phase, e.g., substantially contained in a hydrophobic phase. By “watery” is meant that the droplet comprises water. Usually greater than about 50 mol % of the fluid in a droplet may be H₂O, and it may be typical for at least about 95 mol % or at least about 99 mol % or 100% of the fluid in a droplet to be H₂O (in this context, the “fluid” of the droplet does not include any solute which is ordinarily solid at ambient temperature and pressure). The shape of a droplet is not particularly limited, and may be substantially spheroidal, substantially ellipsoidal, or any other shape. Shape may often depend on the surroundings of the droplet, and a droplet may suffer from compression when confined by solid walls or when in a highly concentrated. emulsion form. The volume of a droplet is not particularly limited, but in some embodiments a droplet may have a volume of from less than 1 femtoliter (fL) to 1 microliter (μL) or even greater. Some exemplary ranges for droplet volume may comprise from about 0.5 ft to about 4 nL; other exemplary ranges for droplet volume may comprise from about 0.5 nL to about 65 nL.

The longest dimension of a droplet is not particularly limited, but may vary from about 1 micrometer to about 1 mm, or may be even greater. Typically, a droplet may comprise a longest dimension of greater than about 1 μm, e.g., from about 1 μm to about 300 μm, especially when employed in a microfluidic system.

In an alternate embodiment, a “droplet” may be defined as an innermost water compartment of a vesicle or or polymersome or liposome, e.g., unilamellar vesicle or liposome or a multilamellar vesicle or liposome. Usually, such vesicle or liposome is a swollen vesicle or a giant vesicle (e.g., a GUV, giant unilamellar vesicle), in which the innermost compartment may have a longest dimension of from about 1 μm to 300 μm. The innermost compartment may comprise solvent and at least one target solute. In certain embodiments, the at least one osmotic body may be an external water phase which is external to the vesicle or liposome noted above. This embodiment (i.e., one which uses a vesicle or liposome) typically differs from an embodiment wherein the osmotic body is in the form of a droplet, since a continuous water phase external to a vesicle is not itself a droplet. Many suitable methods exist for forming vesicles or lipsomes, as would be understood by persons skilled in the art. Some suitable methods with particular applicability include the following references: (1) “Engineering asymmetric vesicles”, by Sophie Pautot, Barbara J. Frisken, and D. A. Weitz, in Proceedings of National Academy of Sciences, Sep. 16, 2003, vol. 100, no. 19, pages 10718-10721; and (2) “Production of Unilamellar Vesicles Using an Inverted Emulsion, by Sophie Pautot Barbara J. Frisken, and D. A. Weitz, Langmuir, 2003, volume 19 (7), pp 2870-2879. Both of the foregoing references are hereby incorporated by reference in their entirety.

As used herein, the “solvent” of the droplet comprises water. In some embodiments, this solvent may be at least about 90% by mole fraction water, or at least about 99 mol % H₂O, or pure water, or ultrapure water. In some embodiments, the solvent may also comprise one or more organic liquid. In some embodiments, the solvent may comprise at least about 90% by mole fraction water and one or more organic liquid, such as methanol or ethanol.

An “osmotic body”, as the term is used herein, is an hydrous material that comprises water and a dissolved osmolyte and exerts an osmotic pressure. A hydrous material comprises water. An osmotic body may be itself a second droplet (e.g., an aqueous droplet), or a continuous liquid phase (e.g., an aqueous phase), or a gel, or a semisolid (e.g., a hydrogel such as one made from agarose). In many embodiments, the osmotic body may be a second aqueous droplet, or a semisolid, or a gel; or the like. As would be readily understood by skilled persons in the art, an osmolyte is any substance contained in the osmotic body (e.g., dissolved in an aqueous droplet, or contained in a hydrogel, etc.) which confers an osmotic pressure to the osmotic body. Usually, the at least one osmotic body may have a greater osmotic pressure than the target droplet, at least at the time of initially contacting the osmotic body and the target droplet.

An example can be a water phase (e.g., one or more droplets) comprising dissolved molecules, polymers and/or electrolytes (e.g., brine, sugar solution, solution of PEG6000). It can also be a hydrogel having osmolyte dissolved therein. It can also be a water phase (comprising a dissolved osmolyte) which is external to a liposome or a vesicle comprising a target solute. However, it is within the scope of this disclosure for there to be embodiments in which the osmotic body explicitly is not a continuous water phase external or a vesicle or liposome. That is, applicants of the present invention contemplate embodiments where the osmotic body may be a droplet or hydrogel or continuous aqueous phase, etc.; but, applicants of the present invention also contemplate embodiments where the osmotic body may be a droplet or hydrogel, etc., but is not a continuous aqueous phase external or a vesicle or liposome.

In many embodiments, the solute (i.e., target solute) may comprise at least one inorganic salt and/or other inorganic molecule (e.g., a metal coordination complex). Examples of inorganic salt are not particularly limited. Examples of suitable inorganic salts may include metal halides, metal salts of organic acids, oxygen-containing metal salts (e.g., K₂CrO₄, KNO₃, KH₂PO₄, KD₂PO₄), metal salts of complex anions (KPF₆, K₃Fe(CN)₆)), or soluble metal (oxy)hydroxides; or the like.

In some embodiments, the inorganic salt solute is crystallized essentially unchanged chemically from the form in which it exists as a solute in the droplet. For example, a method for crystallization (e.g., of NaCl(c) or KH₂PO₄(c)) may recover these materials essentially unchanged and preferably in more pure form.

In other embodiments, the inorganic salt solute may undergo a chemical transformation during the method, e.g., a sol or sol-gel transformation. For example, a droplet of aqueous FeCl₃ or silicic acid may change into hydrous iron oxide or silica, respectively, upon dewatering of the droplet during the process. In many such instances, the product sol or sol-gel will be in the form of a (semi)solid gel or glass. For example, a droplet comprising a dissolved metal salt (e.g., iron salt) may be contacted with an osmotic body to ultimately form an osmotic body to which an metal oxide (e.g., magnetite) particle is attached.

In certain embodiments, the solute may comprise a protein, for example, a membrane protein such as bacteriorhodpsin; or an integral protein. Types of proteins which may be crystallized and/or precipitated by the methods of the invention may include one or more of peptides (e.g. gramicidin); α-helix bundles (e.g. bacteriorhodopsin or ion channel proteins); or β-barrels (e.g. α-hetnolysin, leukocidin or porins); or the like. In such embodiments, the droplet may comprise a precipitant such as a salt (e.g., a metal halide or the like) and/or a polymer (e.g., a polyethyleneglycol or the like). As would be well understood by persons skilled in the art, there are many known methods of crystallizing proteins, including integral proteins and membrane proteins. Some known methods include the so-called hanging drop method, in which a droplet composed of a target protein and dissolved precipitants is placed in a closed chamber, along with a pool of an aqueous liquid with high osmotic pressure (e.g., another droplet, in which is dissolved a salt); water is transported through air from the droplet to the pool. Therefore, in view of this, embodiments of this disclosure contemplate the adhesion of many droplets which had heretofore been used in the hanging-drop process, to many pools of an aqueous liquid with high osmotic pressure which had heretofore been used in the hanging-drop process. In other words, it is envisaged that many pairs which can be used in the hanging-drop method can be advantageously adapted to the present droplet-bilayer system.

In some embodiments, the solute may comprise a protein and the process provides a precipitate (e.g., glassy particle or bead) of the protein. In such embodiments, the droplet may consist essentially of water and one or more proteins, but no precipitants. In such embodiments, the droplet is substantially completely dewatered by the osmotic body across the thin film, such that a dehydrated precipitate of protein(s) is recovered. This may be useful in, e.g., storage of proteins or drug delivery of dewatered proteins.

In certain embodiments, the solute may comprise an organic molecule, such as a small organic molecule, such as an API (active pharmaceutical ingredient) or pharmaceutically acceptable salt thereof. For example, many known APIs require recovery in crystalline form, which form is important for the properties of the API. Embodiments of the present invention may provide methods of crystallizing APIs in an exceptionally rapid fashion, for use in manufacture and/or screening for polymorphic forms.

In certain embodiments, the solute may comprise a polypeptide or a polynucleotide. Some examples of polynucleotides which may be crystallized by methods of the present disclosure may include RNA or DNA (e.g., naturally occurring or synthetic).

As used herein, the term “precipitate” may include any solid phase of a solute, including a crystalline phase, an amorphous phase, a glassy phase, a disordered phase, a gel phase (e.g., a hydrous metal oxide gel), or any other solid form of a solute. For example, embodiments of the present invention may generate one or more crystal (e.g., a single crystalline form or a polycrystalline form) of a solute. Alternatively, embodiments of the present invention may generate colloidal crystals or beads (e.g., microbeads) or a dried gel (e.g., dewatered/dessicated protein). As would be understood by persons skilled in the art in view of the teachings of the present enabling disclosure, the process of water transfer from a target droplet across the thin film may give rise to many different solid forms, depending upon the nature of the solute in the target droplet. In many embodiments of the present invention, the step of allowing solvent to transfer between the droplet and the at least one osmotic body forms at least one crystal of said at least one solute. In other embodiments, the target droplet comprises a metal salt which forms a sol and/or gel when water is selectively removed therefrom (e.g., hydrous ferric salts may form an optionally magnetic iron oxide/hydroxide gel; hydrous silicic acid may form silica gel; or the like).

Generally, the at least one precipitate may be formed substantially within said target droplet. For example, the at least one precipitate may be entirely contained in said droplet, or may be partially contained in said droplet and partially outside said droplet. In some embodiments, the water of the original target droplet is completely consumed by osmotic transfer across the thin film, and thus only the precipitate or crystal remains, with none of the original target droplet remaining.

In some embodiments, the precipitate may comprise a single crystal of the at least one solute, or comprises a polycrystalline precipitate of the at least one solute. In some embodiments, only one single crystal forms in the droplet. In other embodiments, multiple single crystals form in the droplet.

The concentration of solute in the target droplet, initially, is not particularly limited. Generally, the concentration of solute in the target droplet may be chosen to be sufficient to form a crystal having a longest dimension of greater than about 1 micron (e.g., from about 1 micron to about 500 microns, or even higher). Suitable exemplary concentrations of solute in a target droplet may be expressed in a variety of ways: weight ratio of solute (g solute/kg solvent) of from about 20 to about 400; molality of solute of from about 0.3 to about 1.0; osmolality of solute in the target droplet of from about 600 to about 6000 mOsm/kg at 25° C. Other ranges are possible, especially for less soluble solutes (e.g., proteins). These ranges are not intended to be equivalent to each other; rather, they are merely expressions of some exemplary operable concentration ranges.

In certain embodiments, the droplet comprising solvent and at least one solute may be undersaturated in solute at the time the droplet and the osmotic body first adhere to form a thin film therebetween. For example, the subsaturated solution of solute may be concentrated to a supersaturated solution as a result of the method. For example, the subsaturated solution may be at a saturation of from about 0.01 to about 0.99 (more narrowly, from 0.5 to about 0.99 of saturation).

In some embodiments, the droplet comprising solvent and at least one solute may be already supersaturated in solute at the time the droplet and the osmotic body first adhere to form a thin film therebetween. For example, a droplet may be a supersaturated mixture of one or more protein and one or more precipitant (e.g., salt) in a given droplet. In such instance, the one or more protein is generally the solute to be crystallized.

Methods in accordance with embodiments of this invention may comprise contacting at least one osmotic body and a droplet, the droplet comprising solvent and at least one solute, to form at least one thin film between said droplet and said at least one osmotic body; and allowing solvent to transfer between the droplet and the at least one osmotic body to form at least one crystal of said at least one solute; wherein solvent (e.g., water) is transferred in an amount effective to crystallize said at least one solute.

As would be understood by persons skilled in the art, crystallization of a solute from a solvent (e,g., an aqueous solvent) generally requires that the solute be saturated or supersaturated in the solvent. In accordance with embodiments of the present method, solvent (e.g., water) is selectively extracted from the droplet comprising at least one solute, and the solvent is transferred to the osmotic body in an amount effective to crystallize a solute in the droplet. In so doing, the droplet will typically become more saturated in solute (i.e., at or above the equilibrium solubility point of the solute) so that a crystal is nucleated and then grows.

In some embodiments, solvent (e,g., water) is transferred from the droplet to the at least one osmotic body in an amount effective to shrink the droplet substantially completely (e.g., a precipitate and/or crystal forms but the original droplet disappears). In other embodiments, solvent is transferred to the at least one osmotic body in an amount ineffective to shrink the droplet substantially completely (e,g., a precipitate and/or crystal forms but at least some of the original droplet remains). Generally, solvent may be transferred in an amount effective to form a supersaturated solution of said at least one solute in said droplet. For example, the method may be conducted such that the solute is at a relative saturation of at least about 1.01 to about 20.0 at the point at which a crystal first forms (with 1.0 defined as the equilibrium solubility of the solute at the temperature and pressure at which the method is conducted).

In general, the transfer of water solvent between the droplet and the at least one osmotic body, may be promoted or driven by an osmotic gradient or osmotic pressure difference between the droplet and the at least one osmotic body. At least a portion of the water solvent in the target droplet is generally transferred across the thin film from the target droplet to the at least one osmotic body. Typically, the osmolality difference between the droplet and the at least one osmotic body may be selected to result in an supersaturation level in the droplet effective to form a precipitate of the at least one solute in the droplet.

The temperature and pressure of the method is not particularly limited, and either may range independently in the range of from about 0° C. to about 80° C. and from about 0.1 atm to about 10.0 atm. In some embodiments, the method is conducted at a substantially constant temperature (e.g., at a selected temperature in the range of about 20° C. to about 37° C.). In some embodiments, the method is conducted at a variable temperature, in which the temperature is raised and/or lowered from the time at which the droplet and the osmotic body first adhere to form a thin film therebetween, to the time at which a precipitate of at least one solute forms (e.g., at any temperature in the range of from about 0° C. to about 60° C.).

Returning now to the matter of what constitutes an osmolyte: an osmolyte may comprise, e.g., one or more of an acid, a base, a salt, a water-soluble neutral molecule, a polymer, or combination thereof; or the like. Examples of acids may include an organic acid such as acetic acid, or a mineral acid such as H₃PO₄ or H₂SO₄ , or the like. Examples of bases may include mineral bases such as Ca(OH)₂ or NaOH. More typically, an osmolyte may comprise a salt (e.g., an alkali metal halide or pseudohalide, or an alkaline earth metal halide, or other metal salt). Specific examples may include NaCl, ZnCl₂, CaCl₂, or the like. Other convenient osmolytes may comprise a water-soluble organic molecule that exerts an osmotic pressure when dissolved in an aqueous medium (e.g., urea, glycerol, trimethylamine-N-oxide, or sugars such as glucose or sucrose). Alternatively, an osmolyte may comprise a polymeric material (e.g., a water-soluble polymer) such as a polyalkyleneglycol (e.g., one or more type of PEG, e.g., PEG6000). Other kinds of osmolytes would be readily apparent to those skilled in the field. In certain embodiments, the at least one osmotic body comprises an aqueous droplet (e.g., “second droplet”) having sufficient osmolyte dissolved therein so as to provide a greater osmolality than the target droplet.

The concentration of osmolyte in the osmotic body is not particularly limited, but its initial osmolality generally should be at a level sufficient high relative to the initial osmolality of the target droplet to induce precipitation (e.g., crystallization) of at least one solute in the target droplet. In certain embodiments, the initial osmolality difference between the droplet and the at least one osmotic body is selected to result in a supersaturation level in the droplet effective to form a precipitate of said at least one solute.

Some exemplary operable initial ratios for the osmolality of the osmotic body to the osmolality of the target droplet (at the step of contact) may include a value of greater than about 1.5, more particularly greater than about 2, more particularly, greater than about 5. For example, a relative ratio for the osmolality of the osmotic body to the osmolality of the target droplet may be from about 2 to about 20. As would be certainly be understood by the person having ordinary skill in the field, once solvent (e.g., water) is transferred from the droplet to the osmotic body after the time of contact, the osmolality difference will change.

Some exemplary operable ranges for concentration of the osmotic body may include the following: the osmotic body comprises, at said step of contacting, a molality (mole osmolyte/kg solvent) of from at least about 1.0 m, e.g., from about 1,0 m to about 5.0 m, e.g., from about 2 m to about 4 m. Some other exemplary operable ranges for osmolality of the osmotic body may include the following: the osmotic body comprises, at said step of contacting, an osmolality (mOsm osmolyte/kg solvent at 25° C.) of greater than 1000 mOsm/kg, e.g., from about 1000 mOsm/kg to about 12000 mOsm/kg, e.g., from about 3000 mOsm/kg to about 12000 mOsm/kg.

In order the maximize the bilayer adhesion, the method may also be practiced with the proviso that the osmotic body does not comprise iodide ion or thiocyanate ion at concentrations, for either, greater than about 5 M. Too high a concentration of iodide ion or thiocyanate ion (i.e., >5 M) may give rise to too low a contact angle, such that the supersaturation rate is too slow to be practical.

Importantly, in many embodiments, the “osmolyte” in the osmotic body may be different from the at least one solute in the droplet. For example, if the solute in the droplet is a dissolved protein (e.g., lysozyme or a membrane protein), or a dissolved organic compound (e.g., glycine or an active pharmaceutical ingredient), or a dissolved salt (e.g., KH₂PO₄), then the osmolyte (e.g., CaCl₂, or glucose) will be a different chemical compound or chemical composition from the solute. Typically, an osmolyte may be a salt (e.g. NaCl) or organic molecule (e.g., glucose) which is not intended to be crystallized during the process.

Typically, the step of contacting the target droplet and the at least one osmotic body, may comprise adherently and/or adhesively contacting. That is, the target droplet and the at least one osmotic body may adhere such that they have a free energy of adhesion.

Some methods for forming adherent droplets which may be suitable for the methods of the present disclosure, may comprise any of the methods for forming droplet bilayers which are described in US Patent Publications US-2011/0041978-A1, US-2009/0074988-A1, and US-2010-0032627-A1, each of which is hereby incorporated by reference in its entirety. As would be understood by persons skilled in this field, the formation of droplet interface bilayers has been extensively studied for various purposes (e.g., to study the capacitance across a bilayer into which is inserted a membrane channel), and thus the present disclosure specifically contemplates all such methods for formation of droplet interface bilayers.

Without being limited by any theory, a droplet interface bilayer may form when long-range attractive forces between the target droplet and the osmotic body cause the two to adhere to each other; however, typically, droplet adhesion is stabilized against coalescence if a strong and steep repulsion exists at short ranges (e.g., due to the repulsion between tail groups in the lipid bilayer).

To facilitate the stability of the adherence of the target droplet with the osmotic body, at least the target droplet may be in a hydrophobic phase comprising at least one amphiphile. Generally, both the target droplet and the osmotic body are in contact with a hydrophobic phase, usually the same hydrophobic phase. A hydrophobic phase may comprise an oil solvent, such as a hydrocarbon, independently branched or unbranched, substituted or unsubstituted, saturated or unsaturated. In some embodiments, such hydrocarbon may comprise six carbon atoms (e.g., hexane) to 35 carbon atoms, or more narrowly from about 8 to about 30 carbon atoms (examples of the latter being squalene or squalane). However, a hydrophobic phase may also comprise a mineral oil solvent, or may comprise a long-chain alcohol, or fluorinated oils (e.g., fluorinert or the like), or a silicone oils, or a chlorinated hydrocarbon. Combinations of many of these hydrophobic molecules may also be employed for the hydrophobic phase. The hydrophobic phase may also comprise other additives which may alter or influence the thin film, e.g., cholesterol. Of course, in many embodiments, the hydrophobic phase may typically also comprise one or more amphiphilic molecules (e.g., lipid molecules such as monoolein, phospholipid, etc.) which may become incorporated into the thin film.

Generally, a hydrophobic phase may be chosen such that it does not have an appreciable water solubility. If a target water droplet is appreciably soluble in hydrophobic phase, this may give rise to the disadvantageous result of the target droplet shrinking into the hydrophobic phase to the detriment of water being transported across the bilayer. Therefore, in certain embodiments, the hydrophobic phase may be chosen such that it has a solubility for water at a level no greater than that of decane (e.g., no greater than 3.3% water solubility).

In certain embodiments, use of mixtures of hydrophobic molecules (e.g., mixtures of different hydrocarbons), may afford advantages. Some hydrocarbons have a large molecular size, which generally gives rise to large contact angles between droplets. Admixture of a hydrocarbon of a smaller molecular size into one of larger molecular size may afford the advantage of tuning the size of the interdroplet contact area and thus tune the supersaturation rate.

As would be understood by persons skilled in the field, amphiphilic molecules may have both a hydrophilic group and a hydrophobic group. Such amphiphilic molecules may be aligned on the surface of the hydrous osmotic body and the target aqueous droplet, with the hydrophilic groups (or “heads”) towards the hydrous osmotic body and the target aqueous droplet water interface, and the hydrophobic groups (or “tails”) towards the hydrophobic phase.

Typically, amphiphilic molecules may comprise lipid molecules. The lipid molecules may comprise one or more selected from fatty acyls, glycerides (e.g., monoglycerides), glycerolipids, glycerophospholipids, sphingolipids, sterol lipids, prenol lipids, saccharolipids, polyketides, phospholipids, glycolipids, or cholesterol; or the like. The lipid molecules may comprise one or more selected from monoolein; 1,2-dioleoyl-sn-glycero-3-phosphocholine (DOPC); 1,2-diphytanoyi-sn-glycero-3-phosphatidylcholine (DPhPC); palmitoyl oleoyl phosphatidylcholine (POPC); 1-palmitoyl-2-oleoyl-phosphatidylethanolamine (POPE); 1-palmitoyl-2-oleoyl-phosphatidylethanolamine; and 1-palmitoyl-2-oleoylphosphatidylglycerol (POPE/POPG) mixtures; egg lecithin; egg PC; or the like. Other specific lipids to employ may include 1,2-dihexanoyl-sn-glycero-3-phosphocholine [6:0 PC]; or 1,2-didecanoyl-sn-glycero-3-[phospho-rac-(1-glycerol)] [10:0 PG]; or the like. The lipid may optionally be labeled with a fluorescent moiety.

Other lipids which may be appropriate for forming adherent droplets in accordance with the methods of the present disclosure, may comprise any of the lipids which are described in US Patent Publications 2011/0041978-A1 and 2009/0074988-A1, each of which is hereby incorporated by reference in its entirety. Essentially any lipid which is capable of forming a bilayer may be employed according to processes of the present disclosure. In addition to many known phospholipids, the person of ordinary skill in the field may easily determine suitable lipids that can form a bilayer, by following the rules of Israelachvili. Professor Jacob Israelachvili has developed a set of geometric rules regarding the shapes of lipids and amphiphilic surfactants based on a “critical packing parameter” or “shape factor”. These rules are described in the book by J. N. Israelachvili, “Intermolecular and Surface Forces,” (Academic Press, San Diego, Calif., 1992). By following the guidance embodied in the rules described for “critical packing parameter” or “shape factor”, many lipids which are capable of forming a bilayer may be determined, without any undue experimentation. Since persons skilled in the field relevant to the instant invention would be well aware of these “critical packing parameter” or shape factor” rules, a wide scope of lipids is enabled for the present invention.

In certain embodiments, amphiphilic molecules may comprise an amphiphile capable of supporting a highly concentrated emulsion or a high internal phase ratio emulsion, e.g., a PIBSA-based amphiphile, or SPAN-80, or the like.

The amphiphile may be present in the hydrophobic phase, and/or in the target droplet, and/or in the osmotic body. Naturally, the amphiphile may be introduced into the hydrophobic phase by dissolution or suspension, optionally with the prior input of energy (e.g., sonication). An amphiphile may be initially within a target droplet by formulating a target droplet comprising solvent and an least one target solute and also comprising vesicles of the amphiphile. When such target droplet is dispensed into a hydrophobic phase, the amphiphilic molecules will generally migrate from their original vesicle state to the interface between the target aqueous droplet and the hydrophobic phase, forming a monolayer. Similarly, an amphiphile may be initially within an osmotic droplet by formulating an osmotic droplet comprising osmolyte and also comprising vesicles of the amphiphile. When such osmotic droplet is dispensed into a hydrophobic phase, the amphiphilic molecules will generally migrate from their original vesicle state to the interface between the aqueous osmotic droplet and the hydrophobic phase, also forming a monolayer.

The concentration of amphiphile can be readily determined by those skilled in the field. For example, a simple test is to add a specified amount of bilayer-forming amphiphile (e.g., phospholipid) to a hydrophobic phase (e.g., hydrocarbon) and urge two aqueous droplets into proximity. If the droplets form a bilayer upon contact, then the specified amount is at least minimally sufficient. If the droplets merge or coalesce, then generally the specified amount is insufficient. Some exemplary amphiphile concentrations in hydrophobic phase include, independently, from about 1 mM to about 100 mM (e.g., from about 5 mM to about 20 mM); or, from about 1 mg to about 100 mg amphiphile per mL of hydrophobic phase (e.g., from about 10-50 mg/mL hydrophobic phase).

In embodiments of this invention, the method may comprise contacting a plurality of droplets, each droplet of said plurality of droplets comprising solvent and at least one solute, with the at least one osmotic body. For example, in such embodiments, two or more target droplets may adhere to the same osmotic body; each of the two or more target droplets may then form a thin film between each and the osmotic body. For examples, an osmotic body may be formed as a solid gel or a semisolid get (e.g., hydrogel), and then a plurality of target droplets may be placed in contact with such osmotic body. Alternatively, an osmotic body may be in the form of a droplet itself (albeit comprising at least one osmolyte), with two or more adherent target droplets.

Conversely, more than one osmotic body may adhere to a single target droplet (e.g., in a highly concentrated emulsion, or in a microfluidic system in which two or more droplet comprising high osmolyte concentration adhere to a target droplet). This is especially advantageous where the capacity of a single osmotic body (e.g., a first osmotic droplet) is insufficient to dewater the target droplet to form a precipitate, and so a second or subsequent osmotic droplet is adhered to the same target droplet.

In yet other embodiments, a target droplet may adhere to a plurality of other target droplets and also to a plurality of osmotic bodies, where the plurality of osmotic bodies are also droplets. For example, assemblies such as adhesive emulsions, highly concentrated emulsions, gel emulsions, or high internal-phase ratio emulsions (HIPREs), many target droplets may simultaneously adhere to each other and also to a plurality of osmotic droplets at some point prior to the precipitation of at least one solute in at least one target droplet. Precipitation (e.g., crystallization) will be a consequence of solvent (e.g., water) transferring between the target droplet and at least one osmotic droplet through a thin film (e.g., comprising lipid or oligomer).

In accordance with certain embodiments of this disclosure, the method may comprise a preceding step of combining at least two precursor droplets into said droplet comprising solvent and at least one solute. Combining precursor droplets may be by one or more of merging, joining, coalescing, or fusing; or the like. For example, a precursor droplet comprising a protein and another precursor droplet comprising a salt and/or a precipitant may be fused to form a droplet comprising protein solute, and the resultant droplet is contacted with at least one osmotic body to form a thin film therebetween. For example, a first reactant (e.g., CaCl₂) in one or more precursor droplet may be combined with a second reactant (e.g., sodium carbonate) in one or more other precursor droplet to form a resultant droplet comprising solute (e.g., CaCO₃), which is then contacted with at least one osmotic body.

Generally, the step of contacting may comprise urging the droplet into a position proximate the osmotic body to form said thin film therebetween. As used herein, “urging” a droplet to contact an osmotic body, can be accomplished by numerous effective methods, many of which would be readily apparent to the person having ordinary skill in the art. Urging of a droplet can be accomplished by one or more of (1) mechanical motion (e.g., micropipette, microfluidic flow, flow focusing, centripetal force, or the like), or by (2) electrical actuation (e.g., electrowetting or dielectrophoresis, or the like), or by (3) light-induced motion (e.g., optical tweezers, laser light, or the like). Other techniques to move one or droplets can also be used, alone or in combination, including wettability or thermal gradient, or surface acoustic wave. A combination of these methods for urging one or more droplet can be also used. For example, a flowing droplet can have its path perturbed by optical tweezers or electrowetting forces. A typical example of “urging” a droplet may comprise mechanical motion such as microfluidic flow of a droplet, although the present invention is by no means limited thereto. Of course, in the circumstance where an osmotic body is itself a droplet, the osmotic droplet may also be urged or moved by any of the above methods.

It is possible for the amphiphilic molecules on the target droplet to he different from the amphiphilic molecules on the osmotic body. For example, if a target droplet initially comprises vesicles of a first amphiphilic molecule, and then the target droplet is contacted to an osmotic body comprising a second amphiphilic molecule, a thin film comprising an asymmetric bilayer may form therebetween.

The geometric area of the thin film between the target droplet and the osmotic body may be adjustable. The area of the thin film may be adjustable by increasing or decreasing the contact area between the target droplet and the osmotic body. This can be accomplished by moving the center of the target droplet towards or away from the osmotic body, or vice versa, or both. The geometric area of the thin film is not particularly limited. Often, such geometric area may depend upon the size of the target droplet and the osmotic body. Usually, the geometric area of a droplet interface bilayer may be less than the square of the diameter of the target droplet. Controlling the area of the bilayer may confer the advantage of being able to control the supersaturation rate. If the area is made to be relatively small, then the overall rate of water transport across the thin film is lowered, thereby lowering the rate at which supersaturation is achieved in the target droplet.

The method may include a period during which the thin film is cured or stabilized. This can occur in one or more of several ways. One may form a target aqueous droplet in a hydrophobic phase which already contains a bilayer-forming lipid (e.g. an oil-soluble bilayer forming lipid), and then hold the target droplet in the hydrophobic phase for a period of time prior to urging it into adherent contact with an osmotic body to form a thin film therebetween. This period of time may advantageously allow a monolayer and/or bilayer of lipids to form. This period (e.g., from about 0 sec to 1 hr, or from 10 s to 30 min) may be effective to stabilize the lipid bilayer. Alternatively, one may form a target aqueous droplet in a hydrophobic phase, which target droplet already comprises one or more bilayer-forming lipids, and the hydrophobic phase optionally comprises one or more bilayer-forming lipids. In this case, the method may also benefit from the same or a similar stabilization or curing time. The curing may confer the advantage of reducing the likelihood that the target droplet and the osmotic body will coalesce without forming a bilayer.

One may also, optionally, separate a target droplet and an osmotic body after forming a thin film therebetween. This may be accomplished, e.g., by moving the target droplet and the osmotic body away from each other, e.g., by applying a pulling force to one or the other or both, so that the bilayer may spontaneously disassemble. This may confer the advantage of stopping the water transport across the bilayer, if desired. For example, one may adhere a target droplet to an osmotic body by a bilayer, and then allow some water to transport across the bilayer into the osmotic body so as to reach a desired level of supersaturation and/or reach a crystal of desired size; and then, by moving them apart, the process is then arrested or stopped.

Where the osmotic body comprises a hydrogel, a monolayer of amphiphilic molecules will generally self-assemble on the surface of the hydrogel when introduced into a hydrophobic phase comprising a suitable amphiphilic molecule.

A hydrogel may be porous or non-porous. In embodiments, a hydrogel may comprise one or more of agarose, polyacrylamide, polyethylene glycol, nitrocellulose, polycarbonate, polyethersulphone, cellulose acetate, nylon, mesoporous silica; or the like. A semisolid or solid osmotic body may be any shape, without limit. The thickness of a semisolid or solid osmotic body is not particularly limited, and may be a thickness of from about 1 nm to about 10 cm, or more narrowly from about 1 micron to about 1 cm, or more narrowly from about 100 micron to about 1 cm.

A hydrogel-type osmotic body may be kept in contact with a re-hydrating medium, such pool of water or another hydrated material, to prevent drying out of the hydrogel. The rehydrating medium may be agarose gel, or water or polyacrylamide gel; or the like.

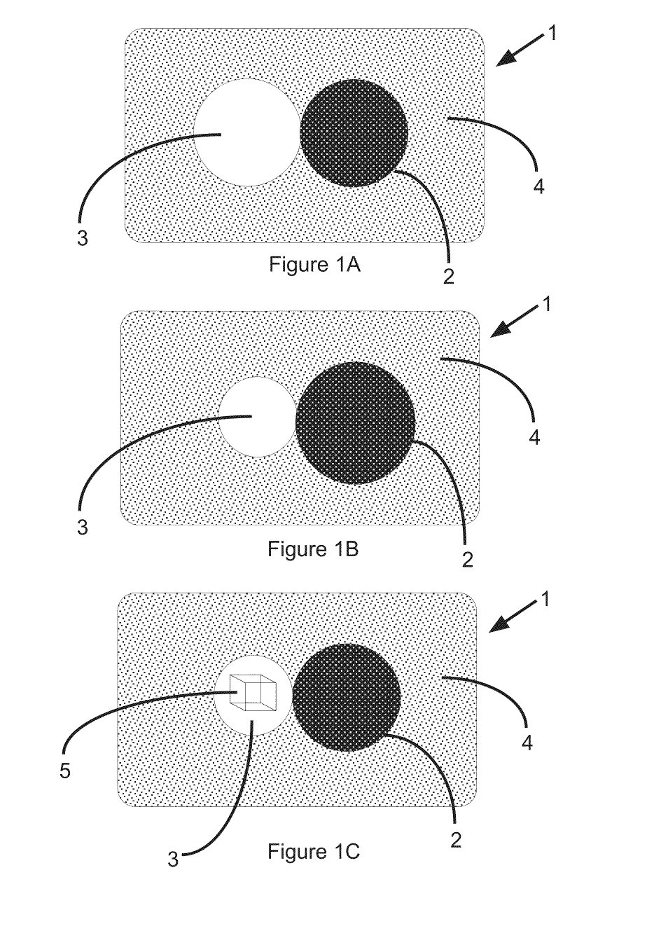

FIG. 1A depicts a highly schematic view of an exemplary system 1 in which a target droplet 3 comprising a solvent and at least one solute, is shown in adherent contact with an osmotic body 2 (here, a droplet comprising water and an osmolyte) via a droplet interface bilayer (not specifically shown in FIG. 1A). In this FIG. 1A, the two droplets are surrounded by a hydrophobic phase 4, such as a phase comprising an oil such as a hydrocarbon. As system 1 develops over time, target droplet 3 is seen to shrink in size in FIG. 1B, as water solvent is transferred into osmotic body 2. Although not shown to scale, FIG. 1B depicts droplet 3 as being smaller in apparent size as a result of this process, and thus more concentrated in solute. Finally, FIG. 1C shows system 1 at a yet later point in time, in which sufficient water has transferred across the droplet interface bilayer to achieve an effective supersaturation in droplet 3, such that at least one crystal 5 of the at least one solute, is formed.

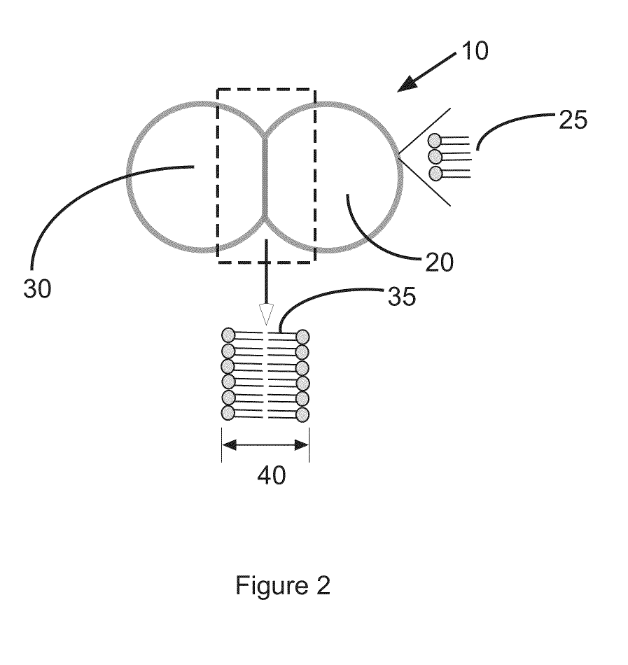

FIG. 2 is a schematic diagram of an exemplary droplet system 10 comprising a pair of droplets 30 and 20 which adhere at a droplet interface bilayer 35. Droplet 30 can be a target droplet and droplet 20 can be an osmotic body in the form of an aqueous droplet comprising an osmolyte. Each of droplet 20 and droplet 30 is surrounded by a monolayer 25 of lipid, at the point where the droplets 20, 30 are in contact with a hydrophobic phase not specifically shown in this view). However, at the point of contact of the droplets 20, 30, a droplet interface bilayer 35 exists, which has a thickness generally shown by 40.

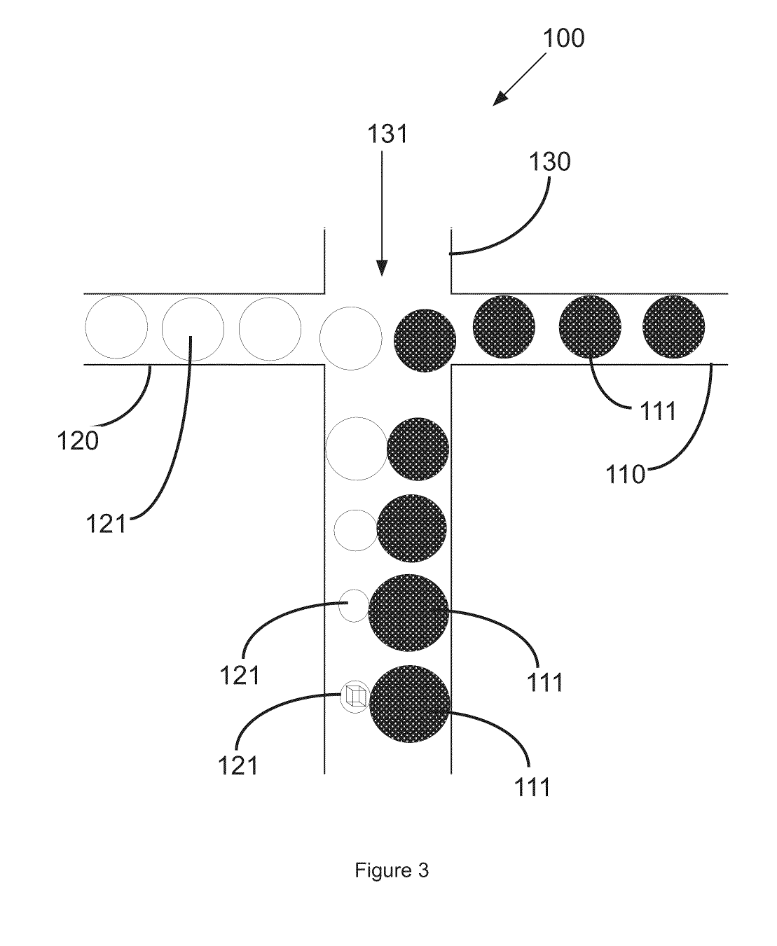

FIG. 3 depicts a schematic view of an exemplary microfluidic system 100 in which droplet pairs 111, 121 may continuously flow into the T-shaped system 100, be urged into contact so as to adhere at a thin film. In this case, droplets 111 are each osmotic droplets, with a sufficient osmotic pressure or osmolality to dewater target droplets 121 across a thin film of a droplet interface bilayer. Target droplets 121 enter the system 100 as isolated aqueous droplets flowing in an oil phase via arm 120, and osmotic droplets 111 enter system 100, also as isolated aqueous droplets flowing in an oil phase, via arm 110. A hydrophobic phase 131 may optionally be injected into system 100 via central conduit 130 to regulate the flow of the respective droplets. Droplet pairs 111, 121 become adherent upon being urged into contact via the microfluidic flow, and then, after an effective period of time, a crystal of at least one solute forms within a droplet 121, as a result of solvent transfer across the thin film.

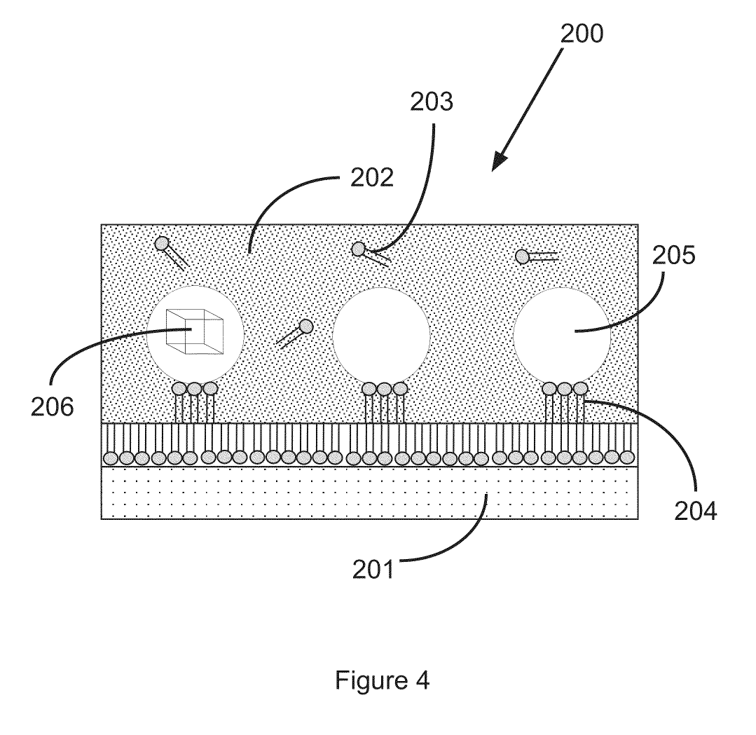

FIG. 4 is a schematic depiction of an exemplary arrayed system 200, in which a plurality of target aqueous droplets 205, each of which comprises at least one target solute, are arrayed on a hydrogel support 201. The hydrogel support 201 comprises at least one osmolyte such that it is capable of acting as an osmotic body. Overlaying hydrogel support 201 is a hydrophobic phase 202 (e.g., an oil or hydrocarbon) in which is dissolved at least one lipid 203. Since the hydrogel support 201 is a hydrous material, a bilayer 204 of the lipid molecules 203 may self-assemble at the interface between hydrogel support 201 and aqueous droplets 205. Bilayer 204 facilitates the dewatering of solvent from one or more droplet 205 such that a crystal 206 of at least one solute forms.

### EXAMPLES

### Example 1

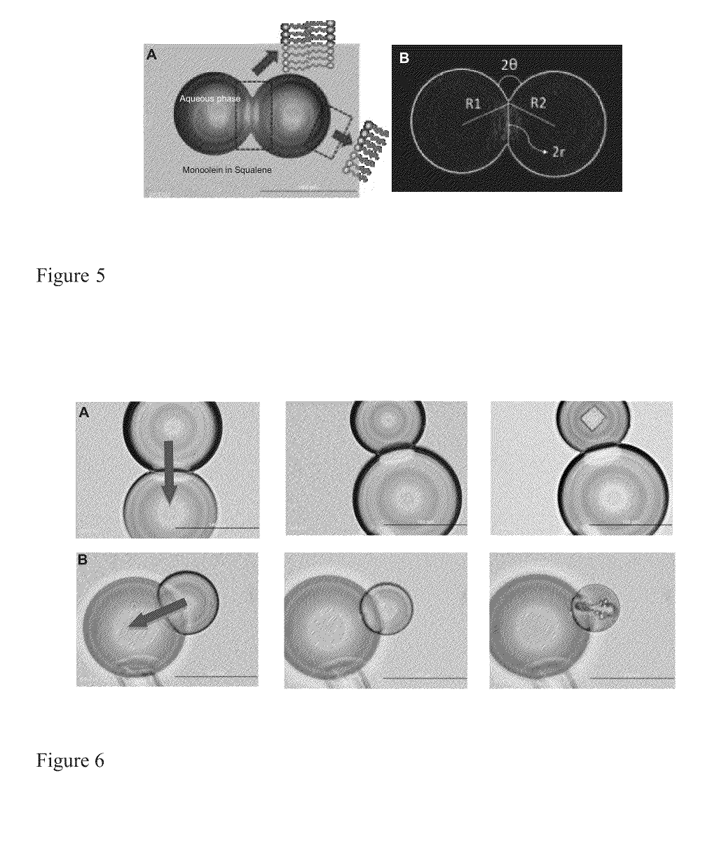

Two pure aqueous droplets (˜100 micron; all droplet dimensions reported here are for diameter) were brought into contact in a squalene solution of monoolein (9 mM), and the droplets adhere to form a DIB (FIG. 5a). Droplet pairs using monoolein in a solvent of large molecular size (such as squalene) generally have a large contact zone, the size and area of which can be measured optically. Relevant radii (FIG. 5b) were measured upon images directly recorded using CCD camera attached to a microscope. The typical contact angle θ between two pure water droplets in squalene containing monoolein was 25°, while droplet pairs containing high salt concentration, e.g., 4.1 M CaCl₂, show far larger contact angles, as high as 47°.

Typically, droplet pairs were formed by placing droplets adjacent to each other with micropipet manipulation. Droplets on a borosilicate glass slide forming the bottom of the oil solution chamber did not wet the glass, likely due to the presence of the monoolein in the oil solution which effectively hydrophobized the surface. The resultant adherent droplets were allowed to rest unconstrained on the glass slide. Similar results were obtained for adherent droplet pairs held by slight suction by respective pairs of micropipets.

### Example 2

When two droplets of osmotically imbalanced droplets adhered at a bilayer, water transport immediately commenced. FIG. 6 shows examples of such systems. In each case, there was DIB between adherent droplets, one containing a crystallizable solute and the other droplet containing an osmolyte, CaCl₂. In FIG. 6a, the upper droplet contains KPF₆ (starting concentration of 6% w/v; equilibrium solubility 7.95% at 25° C.), with a measured osmolality of 485 mOsm/kg. The lower droplet contained a relatively concentrated solution of osmolyte (3 M CaCl₂, 12 Osm/kg). The osmotic gradient drives water transport through the droplet bilayer. This resulted in a marked change in droplet diameter within seconds, until an effective level of supersaturation was reached so as to induce a crystallization event. FIG. 6b demonstrates successful crystallization of another inorganic solute, potassium hexacyanoferrate(III): the rightmost droplet (yellow) contains an initial concentration of 35% (w/v) K₃Fe(CN)₆ (equilibrium solubility 46.4% at 20° C.) adherent to a droplet of 3 M CaCl₂. For both cases, crystallization was complete in less than 60 s: typically, one crystal of the solute grew to the full size of its droplet compartment. Measuring the changes in droplet diameter allowed us to determine the supersaturation rate and solute concentration at which a crystal appears (Cₒₙₛₑₜ). Similar nucleation behavior for further test solutes (K₂SO₄, KNO₃) was also successful.

Further examples of crystallizations of a target solute are shown in Table 1 below.

TABLE I

| | Initial | | Lipid & | |
|---|---|---|---|---|
| | concen- | | Concentration | |
| Target | tration | Hydrophobic | in hydrophobic | Osmotic |
| Solute | (w/v) | solvent | solvent | droplet |
| K₂SO₄ | 5% | squalene | monoolein, 8 mM | CaCl₂ (aq), 3M |
| K₂SO₄ | 10% | squalene | monoolein, 8 mM | CaCl₂ (aq), 3M |
| K₃Fe(CN)₆ | 35% | squalene | monoolein, 8 mM | CaCl₂ (aq), 3M |
| KNO₃ | 30% | squalene | monoolein, 8 mM | CaCl₂ (aq), 3M |
| KPF₆ | 6% | squalene | monoolein, 8 mM | CaCl₂ (aq), 3M |

Aspects of the present disclosure provide many inventive technical effects. For example, crystallization may be achievable in as little as 1-10 seconds. The presently described systems may arrive at effective supersaturation conditions in an accelerated fashion, due to the presence of a nanomembrane. Most prior art references never crystallize in less than several minutes. Furthermore, one may induce the crystallization of solutes within droplets under isothermal conditions. This is a favorable condition for adapting the present methods to microfluidic applications. In contrast, may known membrane crystallization methods cannot be adapted to microfluidic applications. Furthermore, one may attain a single mononucleation event. That is, methods of the present disclosure may afford only a single crystal within each droplet. In contrast, many known membrane crystallization methods never give such single crystals within isolated droplets.

The systems described here offer the potential for remarkably efficient and highly configurable new modalities for crystal nucleation at the droplet level. Akin to many prior droplet crystallization systems, crystals can be formed using only small quantities of solute. However, to drive supersaturation, prior systems often require cooling or solvent permeation through walls of the microfluidic chamber. In contrast, the presently described system arrives at effective supersaturation conditions in an accelerated fashion, due to the thin film through which solvent is selectively extracted.

Those skilled in the art would readily appreciate that all parameters listed herein are meant to be exemplary and that actual parameters will depend upon the specific application for which the methods and apparatus of the present invention are used. It is, therefore, to be understood that the foregoing embodiments are presented by way of example only and that, within the scope of the appended claims and equivalents thereto, the invention may be practiced otherwise than as specifically described. It is to be understood that the foregoing description is intended to illustrate and not to limit the scope of the invention, which is defined by the scope of the appended claims. Other embodiments are within the scope of the following claims.

I claim:

1. A method comprising:
contacting at least one osmotic body and a droplet, said droplet comprising solvent and at least one solute, to form at least one thin film between said droplet and said at least one osmotic body; and
allowing solvent to transfer between said droplet and said at least one osmotic body to form a precipitate of said at least one solute.

2. The method in accordance with claim 1, wherein the solute is water-soluble, and the precipitate of said at least one solute is crystalline.

3. The method in accordance with claim 1, wherein the method comprises contacting a plurality of said droplets and the at least one osmotic body.

4. The method in accordance with claim 1, wherein solvent is transferred in an amount effective to form a supersaturated solution of said at least one solute in said droplet.

5. The method in accordance with claim 1, wherein the method comprises a preceding step of combining at least two precursor droplets to form said droplet comprising solvent and at least one solute.

6. The method in accordance with claim 1, wherein said solute comprises at least one of protein, active pharmaceutical ingredient or pharmaceutically acceptable salt thereof, polypeptide, nucleotide, or inorganic molecule.

7. The method in accordance with claim 1, wherein said precipitate comprises a single crystal of said at least one solute, and wherein one single crystal forms in said droplet.

8. The method in accordance with claim 1, wherein the at least one osmotic body is a second droplet, or is a water phase outside of a vesicle or liposome or polymersome, or is a gel.

9. The method in accordance with claim 1, wherein the thin film is a semipermeable membrane having a thickness of less than about 20 nm.

10. The method in accordance with claim 1, wherein the thin film comprises a bilayer.

11. The method in accordance with claim 1, wherein the thin film comprises a thickness between about 2 nm and about 10 nm.

12. The method in accordance with claim 1, wherein the thin film comprises at least one polymer.

13. The method in accordance with claim 1, wherein the droplet is a water droplet in an oil phase, or is a central compartment of a vesicle, liposome, or polymersome.

14. The method in accordance with claim 1, wherein a ratio of an osmolality for the osmotic body to an osmolality of the droplet, at the step of contact, is from about 2 to about 20.

15. The method in accordance with claim 1, wherein said droplet comprises a mixture of a protein and a precipitant.

16. The method in accordance with claim 1, wherein the step of contacting comprises a microfluidic flow of the droplet.

17. A composition comprising:
a plurality of compartments comprising at least one crystalline active pharmaceutical ingredient, said compartments encapsulated by a lipid bilayer,
wherein said composition has been made by a process in accordance with claim 1.

18. A composition comprising,
a plurality of first aqueous droplets comprising at least one solute and a plurality of second aqueous droplets comprising at least one osmolyte, at least one of the plurality of first aqueous droplets adhering to at least one of the plurality of second aqueous droplets at an interface comprising a droplet interface bilayer; and
wherein at least one of the plurality of first aqueous droplets further comprises at least one crystal of said at least one solute.

19. The composition in accordance with claim 18, wherein the composition further comprises a continuous hydrophobic phase in contact with the plurality of first aqueous droplets and the plurality of second aqueous droplets.

20. The composition in accordance with claim 18, wherein the composition is a high internal phase emulsion, high internal phase ratio emulsion, highly concentrated emulsion, or a gel emulsion.
